(19) United States
(12) Patent Application Publication
(10) Pub. No.: US 2010/0089447 A1
(43) Pub. Date: Apr. 15, 2010

(54) CONDUCTIVE GRIDS FOR SOLAR CELLS

(75) Inventors: Bulent M. Basol, Manhattan Beach, CA (US); Burak Metin, Milpitas, CA (US); Richard Snow, Redwood City, CA (US)

Correspondence Address: PILLSBURY WINTHROP SHAW PITTMAN LLP, P.O. BOX 10500, MCLEAN, VA, 22102, US

(73) Assignee: SoloPower, Inc., San Jose, CA (US)

(21) Appl. No.: 12/577,137

(22) Filed: Oct. 9, 2009

Related U.S. Application Data
(60) Provisional application No. 61/104,031, filed on Oct. 9, 2008.

(51) Int. Cl. H01L 31/00; H01L 31/18

(52) U.S. Cl. 136/256; 438/98; 257/E21.211

(57) ABSTRACT

Embodiments of the present inventions provide structures and methods for manufacturing high electrical conductivity grid patterns having minimum shadowing effect on the illuminated side of the solar cells. To manufacture a conductive grid for a solar cell, a first conductive layer is initially formed over a transparent conductive oxide layer of a solar cell. The first conductive layer has a pattern including a busbar and fingers connected to the busbar. Next, a second conductive layer is formed on the first conductive layer. In one embodiment, the first conductive layer includes silver and the second conductive layer includes carbon nano tube material, or the first conductive layer includes carbon nano tube material and the second conductive layer includes silver.

### RELATED APPLICATIONS

This application claims priority from U.S. Provisional Patent Application Ser. No. 61/104,031 filed Oct. 9, 2008 and is incorporated herein by reference.

### FIELD OF THE INVENTIONS

The present inventions generally relate to solar cell fabrication and, more particularly, to fabrication of thin film solar cells and modules.

### DESCRIPTION OF THE RELATED ART

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(S_{y}Se_{1-y})ₖ, where 0≦x≦1, 0≦y≦1 and k is approximately 2, have already been employed in solar cell structures that yielded conversion efficiencies approaching 20%. It should be noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which comprises a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. As shown in FIG. 2 in top view, metallic grids 30 may also be deposited over top surface 16 of the transparent layer 14 to reduce the effective series resistance of the device. The top surface 16 forms the illuminated surface of the solar cell 10. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

If the substrate 11 of the CIGS(S) type cell shown in FIG. 1 is a metallic foil, then under illumination, a positive voltage develops on the substrate 11 with respect to the transparent layer 14. In other words, an electrical wire (not shown) that may be attached to the substrate 11 would constitute the (+) terminal of the solar cell 10 and a lead (not shown) that may be connected to the metallic grid 30 would constitute the (−) terminal of the solar cell.

After fabrication, individual solar cells are typically assembled into solar cell circuits by interconnecting them in series electrically, i.e. by connecting the (+) terminal of one cell to the (−) terminal of a neighboring cell. This way the total voltage of the solar cell circuit is increased. The solar cell circuit is then laminated into a protective package to form a photovoltaic module.

As shown in FIG. 2 the metallic grid 30 or finger pattern is deposited on the illuminated side of the solar cell device and include one or more busbars 32 and multiple fingers 34 to carry the current from various parts of the device to the busbars 32. Busbars 32 and fingers 30 generally comprise metals with low electrical resistivity such as silver or silver alloys, which can be ink-deposited or screen printed over the illuminated surfaces using silver-based inks or pastes. However, although the low electrical resistivity of such materials plays an important role in their choice, in operation, there is a trade off relationship between their size and their electrical resistivity, which critically depends on the cross sectional area of the fingers and the busbars. Since the fingers are spread over the illuminated surface, in order to reduce the shadowing effect caused by their size on the illuminated surface, their width needs to be minimized while their height needs to be maximized to keep the resistance low. However, in ink deposition or screen printing approaches, when the width of the finger is reduced to minimize the shadowing loss, the height of the finger also gets reduced due to the nature of these processes and the nature of the inks and pastes used. Therefore, for narrow fingers the cross sectional area gets reduced and the resistance of the finger increases causing the overall efficiency of the solar cell to go down despite the fact that more light enters the device.

From the foregoing, there is a need in the thin film solar cell industry for improved grid structures and manufacturing methods that allows fabrication of narrow fingers with low resistance so that the conversion efficiency of the solar cells may be improved.

### SUMMARY

Embodiments of the present inventions provide structures and methods for manufacturing high electrical conductivity grid patterns having minimum shadowing effect on the illuminated side of the solar cells.

### BRIEF DESCRIPTION OF THE DRAWINGS

FIG. 1 is a side schematic view of a solar cell of the prior art;

FIG. 2 is a top schematic view of the solar cell with a conductive grid over the top surface;

FIG. 3A is a top schematic view of a solar cell having an embodiment of a conductive grid;

FIG. 3B is a schematic side view of the solar cell shown in FIG. 3A;

FIG. 4 is a schematic side view of a finger structure of the conductive grid shown in FIGS. 3A-3B;

FIG. 5 is a schematic side view of an alternative finger structure for the conductive grid;

FIG. 6 is a top schematic view of a solar cell having another embodiment of a conductive grid;

FIG. 7 is a schematic side view of a finger structure of the conductive grid shown in FIG. 6; and

FIG. 8 is a schematic side view of a finger structure of another embodiment of a conductive grid.

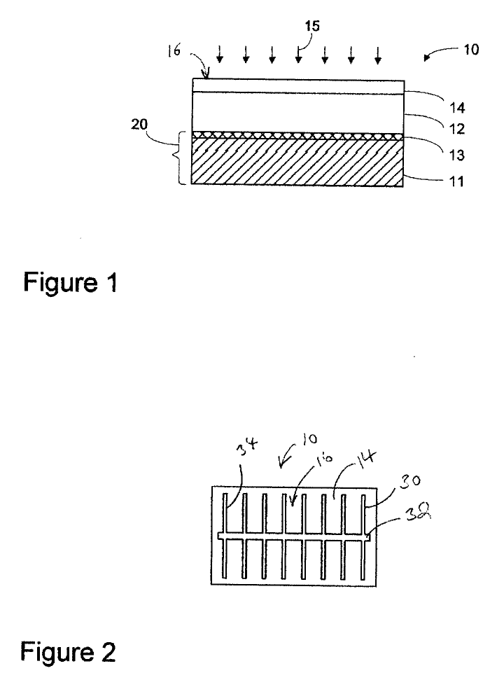

### DETAILED DESCRIPTION OF THE PREFERRED EMBODIMENTS

The preferred embodiments provide structures of and methods for the formation of low resistivity conductive grids over illuminated side of photovoltaic cells or solar cells. In one embodiment, the conductive grid of the present invention comprises nano-tube materials, preferably highly conductive carbon nano-tubes, which have more preferably been purified in order to remove excess carbon to ensure that they are most highly conductive. During the process, a layer of the carbon nano-tube material having the pattern of the conductive grid is positioned over the top surface of a transparent conductive layer of a solar cell structure. The layer of carbon nano-tube material may be selectively deposited on a layer of conductive material which may have the same grid pattern and may be deposited on the top surface of the transparent conductive layer.

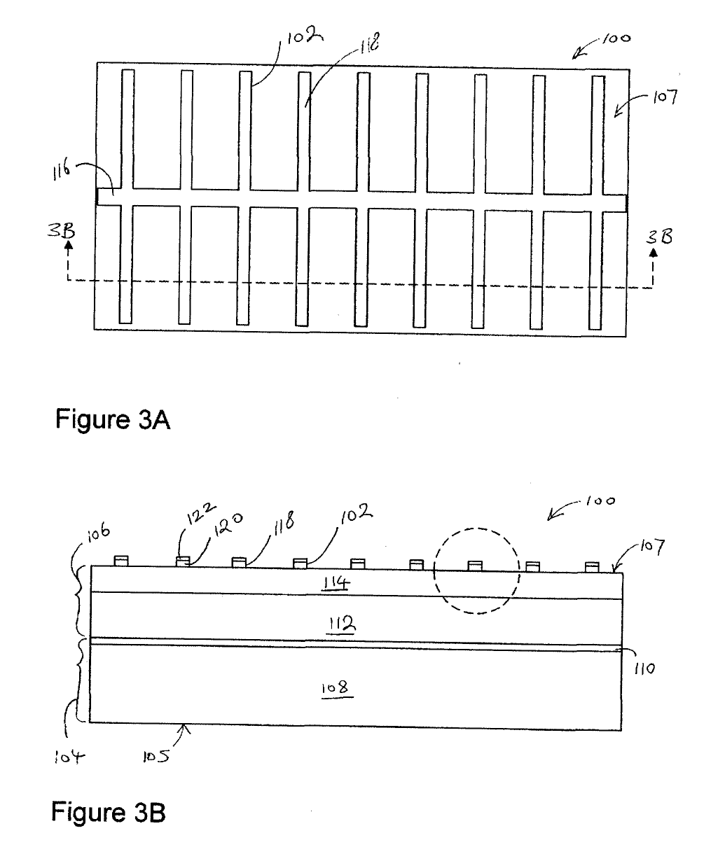

FIGS. 3A and 3B show an exemplary solar cell 100 having a conductive grid 102 in top view and side view, respectively. The solar cell 100 comprises a base portion 104 having a back surface 105 and a front portion 106 having a front surface 107. The base portion 104 includes a substrate 108 and a contact layer 110 formed on the substrate. For this embodiment, a preferred substrate material may be a metallic material such as stainless steel, aluminum (Al) or the like. An exemplary contact layer material may be molybdenum (Mo). The front portion 106 may comprise an absorber layer 112, such as a CIGS absorber layer which is formed on the contact layer 110, and a transparent layer 114, such as a buffer-layer/TCO stack, formed on the absorber layer where TCO stands for transparent conductive oxide. An exemplary buffer layer may be a (Cd, Zn)S layer. An exemplary TCO layer may be a ZnO layer, an indium tin oxide (ITO) layer or a stack comprising both ZnO and ITO. The conductive grid 102 includes a busbar 116 and conductive fingers 118 may be formed over the front surface 107 which is also the surface of the TCO layer of the transparent layer 114.

In this embodiment, the conductive grid 102 may have a composite structure including first conductive layer 120 formed over the surface 107 of the transparent layer 114, and a second conductive layer 122 formed over the first conductive layer 120. The first conductive layer may be made of a metallic material such as silver (Ag) having the pattern of the conductive grid shown in FIG. 3A. The silver layer may be ink-deposited over the surface 107 of the transparent layer 114. The second conductive layer 122 may be made of a material which has a lower electrical resistivity than the material of the first conductive layer 120. The second conductive layer may be made of a carbon nano-tube material.

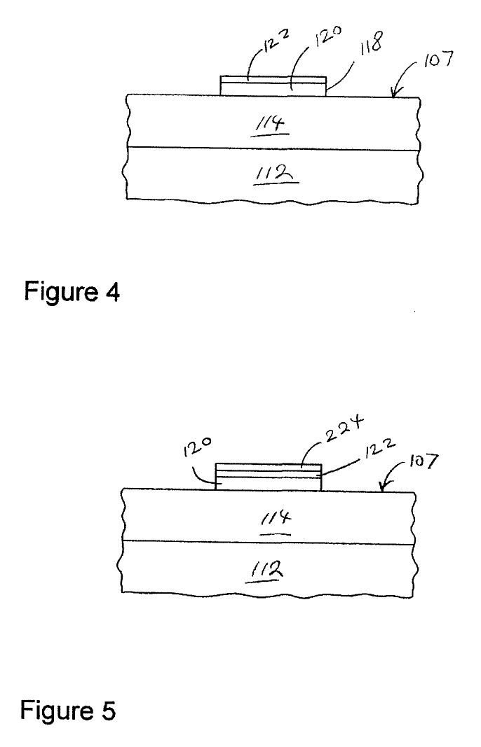

FIG. 4 shows a detail view of one of the fingers 118 of the conductive grid 102 in the circled area of FIG. 3B. As shown in the side cross sectional view of the finger 118 shown in FIG. 4, the conductive grid 102 includes the first conductive layer 120 and the second conductive layer 122. The first conductive layer 120 may have a width in the range of 20-100 micrometers, preferably 40-80 micrometers and a height in the range of 1-15 micrometers, preferably 5-10 micrometers. The width and height of the second conductive layer 122 may be equal to or less than the width and height of the first conductive layer 120. The combined electrical sheet resistance of the first and second conductive layers 120 and 122 of the finger 118 is less than that of a finger having the same dimensions and made of only the first conductive layer material, e.g., silver, since the resistivity of carbon nano-tubes may be much less than that of silver.

The conductive grid 102 may also be formed with three or more layers. As shown in FIG. 5, for three layer case, a conductive finger 218 of the conductive grid may include the first conductive layer 120, the second conductive layer 122 and a third conductive layer 214. The third conductive layer 214 may be made of the material of the first conductive layer 120. In this embodiment the second conductive layer 122 is sandwiched and protected by the first conductive layer 120 and the third conductive layer 214. The third conductive layer 214 may comprise materials including silver. The third conductive layer 120 may be similar in composition to the first conductive layer 120. This helps maximize the physical contact and therefore the electrical contact between the second conductive layer 122 and the first and third conductive layers. As a result the sheet resistance of the composite structure of the finger 218 is lowered.

One benefit of the present inventions may be demonstrated by the following example. For example, there are prior art screen printing techniques used to deposit Ag-based finger patterns of TCO surfaces using Ag-based screen printing pastes. Using such techniques, it is possible to deposit fingers with a width of 150 micrometers and height of 20 micrometers. If one attempts to reduce the finger width to 50 micrometer, for example, to reduce the shadowing loss, the height of the finger also gets reduced to the 5-10 micrometer range. If the height of the finger is reduced to 5 micrometers, simple arithmetic suggests that with the reduced width and height, the sheet resistance of the finger would be 12 times higher than that of the original 150 micrometer wide finger. To get any benefit from the reduced finger width, the sheet resistance of the finger needs to be kept constant or even reduced. This can be achieved by embodiments described herein. Referring back to FIG. 3B, the first conductive layer 120 may be formed over the surface 107 of the transparent layer 114 using, for example, Ag-paste screen printing technique yielding a 50 micrometer wide and 5 micrometer high Ag-based initial grid pattern. The second conductive layer 122 may then be selectively deposited and formed over the first conductive layer 120 to a thickness of, for example, 1-5 micrometers using a technique such as electrophoresis. Since the electrical resistance of the initial grid pattern is lower than that of the transparent layer 114, it is possible to deposit the second conductive layer 122, which may be a layer of carbon nano-tubes, on the first conductive layer 120 but not on the transparent layer 114. It should be noted that the transparent layer 114 may have a sheet resistance of 20-60 ohms per square compared to the sheet resistance of the Ag-based initial grid pattern which may be lower than 1 ohm per square. If necessary, masking may also be used to deposit the second conductive layer substantially on the first conductive layer but not on the transparent layer.

The second conductive layer may be made of a carbon nano-tube material yielding a sheet resistance that is much lower than that of the first conductive layer 120. If this sheet resistance is, for example, 10-12 times lower than the sheet resistance of the first conductive layer, then the composite structure of the conductive grid 102 would offer a sheet resistance that would be equivalent to the sheet resistance of a 150 micrometer wide fingers. Obviously, the reduced shadowing of the 50 micrometer wide fingers would improve the efficiency of the solar cells.

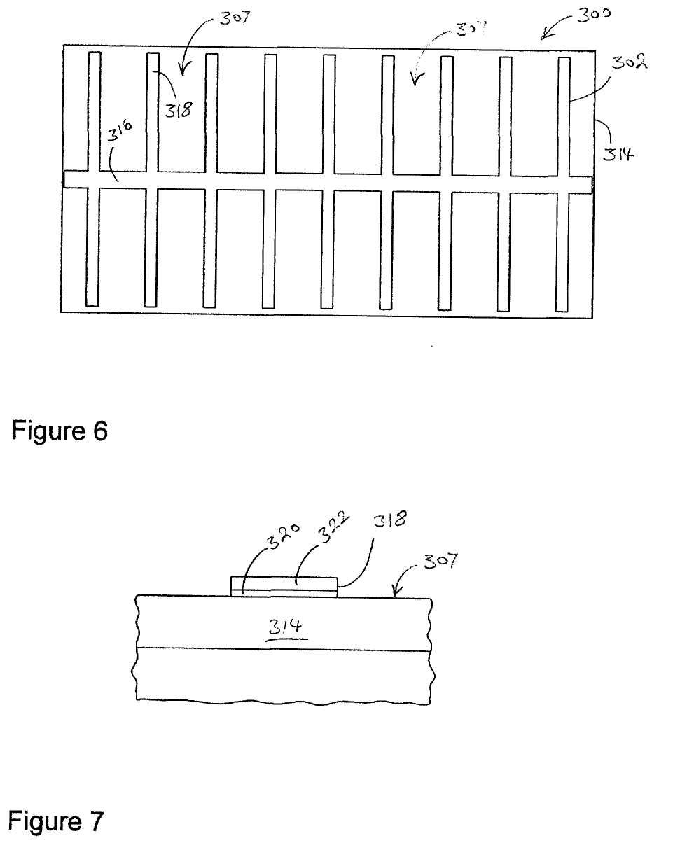

FIG. 6 shows in top view an exemplary solar cell 300 having another embodiment of a conductive grid 302 formed on a front surface 307 or a light receiving surface of the solar cell 300. As described above, in a solar cell, a transparent layer is formed on an absorber layer and includes a buffer-layer formed on the absorber layer and a TCO layer formed on the buffer layer. Therefore, the front surface 307 is also the surface of the TCO layer of the transparent layer 314. The conductive grid 302 includes a busbar 316 and conductive fingers 318 and is formed over the front surface 307.

As shown in FIG. 7 in detail side view of one of the fingers 118 of the conductive grid 302, in this embodiment, the conductive grid 302 is formed by forming a first conductive layer 320, having the grid pattern shown in FIG. 6, over the surface 307 of the TCO layer and then forming a second conductive layer 322 on the first conductive layer 320. However, differing from the previous embodiment, the electrical resistivity of the material of the first conductive layer 320 is preferably less than the electrical resistivity of the second conductive layer. The first conductive layer 320 may comprise carbon nano tube material which may be initially deposited on the surface 307 to form the desired grid pattern. The first conductive layer 320 is then capped by the second conductive layer 322 which may be a silver layer so as to keep the first conductive layer 320 in place. The silver layer may be screen printed on the pattern of the carbon nano tube layer. The width and height of the second conductive layer 322 may be equal to or less than the width and height of the first conductive layer 320. The combined electrical sheet resistance of the first and second conductive layers 320 and 322 of the finger 118 is less than that of a finger having the same dimensions and made of only the second conductive layer material.

Another embodiment provides a method to lower the contact resistance between a transparent layer, such as ZnO or ITO layer at a light receiving side of a solar cell, and a conventional Ag based conductive grid so as to increase the overall efficiency. Although such conventional Ag based grids have very low bulk resistivity, relatively high contact resistance at the interface of grid-transparent layer and chemical incompatibility with CIGS cells prevents the full use of this low bulk resistivity. The contact resistance may be caused by the chemical incompatibility between the transparent layer and the specific material of the conductive grid. Another conductive material having better chemical compatibility and thus low contact resistance with the transparent layer may be applied between the conductive grid and the transparent layer. The bulk resistivity of this conductive material may be less than or equal to the conductive grid material. Both conductive materials may be produced from Ag-based (either particle or flake) inks that can be screen printed onto the cells to form fingers and bus bars.

The following embodiment exemplifies a process to form a conductive grid layer comprising a first conductive grid material film deposited on the transparent layer and a second conductive grid material film deposited on the first conductive grid material film. In the exemplary embodiment, the first conductive grid material film may comprise silver. The first conductive grid material film may have a bulk resistivity in the range of 20-50 micro Ohm cm, typically 30-35 micro Ohm cm. The contact resistance between the first conductive grid material film and the transparent layer for example ITO may be in the range of 3-50 milli Ohm cm², preferably in the range of 3-15 milli Ohm cm², and typically 6 milli Ohm cm². The second conductive grid material film may also comprise silver. The second conductive grid material film may have a bulk resistivity in the range of 5-12 micro Ohm cm, typically 8 micro Ohm cm. As seen, the bulk resistivity of the second conductive grid material film is less than the first conductive grid material film. The first conductive grid material film is lower in bulk resistivity by about a factor of 3 than the second conductive grid material film. The contact resistance between the second conductive grid material film and the transparent layer (for example ITO) may be in the range of 14-30 milli Ohm cm², typically 23 milli Ohm cm². As seen, the contact resistance of the second conductive grid material film is less than the first conductive grid material film. The contact resistance between the first conductive grid material film and the second conductive grid material film is negligible.

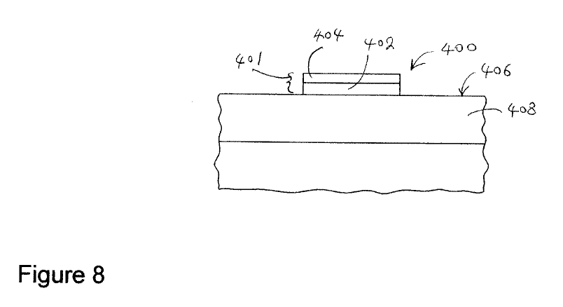

FIG. 8 shows a structure of a finger 400 representing the structure of a conductive grid layer 401 formed on a transparent layer 408 according to an embodiment. The lateral shape of the conductive grid layer 401 is similar to the conductive grids 100 and 300 shown in FIGS. 3A and 6 formed on the transparent layers or transparent conductive oxides of the solar cells. The finger 400 includes the first conductive grid material film 402 formed over a surface 406 of the transparent layer 408 and the second conductive grid material film 404 formed on the first conductive grid material film. Both the first conductive grid material film and the second conductive grid material film form the conductive grid layer 401 on the transparent layer 408. As mentioned above, the first and second conductive grid material films both comprise silver and are deposited from ink solutions containing substantially silver by weight by screen printing each ink solution to form fingers and busbars of the conductive grid pattern. For example, a first ink solution may first be printed onto the transparent layer and cured to form the first conductive grid material film having the desired conductive grid shape. Then, a second ink solution may be printed onto the first conductive grid material film and cured to form the second conductive grid material film having the desired conductive grid layer shape. In a particular embodiment, the first ink solution is an ink type called PV-412 from Dupont® Inc. Due to the combined low bulk resistivity and low contact resistance of the films the efficiency provided with the conductive grid layer is higher than the efficiency could be provided with a conductive grid layer formed with the second conductive grid material. Thickness of the first conductive grid material film may range from 3 um to 50 um, but a preferred thickness probably 8 um. Width of the first conductive grid material film may range from 30 um to 250 um, but a preferred width is 200 um. Thickness of the second conductive grid material film may range from 3 um to 30 um, but a preferred thickness is probably 10 um. Width of the second conductive grid material film could range from 30 um to 250 um, but a preferred width is 100 um.

Although the present inventions are described with respect to certain preferred embodiments, modifications thereto will be apparent to those skilled in the art.

We claim:

1. A method of manufacturing a conductive grid for a solar cell, comprising:
depositing a first conductive layer over a light receiving surface of a solar cell, wherein the first conductive layer has a pattern including a busbar and fingers connected to the busbar; and
depositing a second conductive layer onto the first conductive layer, wherein at least one of the first conductive layer and the second conductive layer includes conductive carbon nano tube material.

2. The method of claim 1, wherein the first conductive layer includes a metallic material and the second conductive layer includes conductive carbon nano tube material.

3. The method of claim 2, wherein the metallic material is silver.

4. The method of claim 3, wherein the step of depositing the first conductive layer comprises one of depositing silver from a silver paste using a screen printing process and depositing silver from an ink using an ink deposition process.

5. The method of claim 2, wherein the step of depositing the second conductive layer onto the first conductive layer comprises depositing the conductive carbon nano tube material using electrophoresis process.

6. The method of claim 1, wherein the first conductive layer includes the conductive carbon nano tube material and the second conductive layer includes a metallic material.

7. The method of claim 6, wherein the metallic material is silver.

8. The method of claim 7, wherein the step of depositing the first conductive layer comprises depositing the conductive carbon nano tube material using electrophoresis process.

9. The method of claim 8, wherein the step of depositing the second conductive layer onto the first conductive layer comprises one of depositing silver from a silver paste using a screen printing process and depositing silver from an ink using an ink deposition process.

10. A conductive grid formed on a light receiving surface of a solar cell, comprising:
a first conductive layer deposited over a light receiving surface of a solar cell, wherein the first conductive layer has a pattern including a busbar and fingers connected to the busbar; and
a second conductive layer deposited onto the first conductive layer, wherein one of the first conductive layer and the second conductive layer is a conductive carbon nano tube material layer and wherein the remaining one of the first conductive layer and second conductive layer is a metallic layer.

11. The conductive grid of claim 10, wherein the light receiving surface is a surface of a transparent conductive oxide comprising one of zinc oxide and indium tin oxide.

12. The conductive grid of claim 11, wherein the metallic layer comprises silver.

13. The conductive grid of claim 12, wherein the metallic layer has a thickness in the range of 20-100 micrometers.

14. The conductive grid of claim 13, wherein the conductive carbon nano tube material layer has a width in the range of 1-15 micrometers.

15. The conductive grid of claim 14, wherein the conductive carbon nano tube material layer has a thickness in the range of 1-5 micrometers.

16. The conductive grid of claim 12, wherein the sheet resistance of the metallic layer is less than 1 ohm per square.

17. The conductive grid of claim 16, wherein the sheet resistance of the conductive carbon nano tube material layer is at least 10-12 times lower than the sheet resistance of the metallic layer.

18. A method of manufacturing a conductive grid for a solar cell, comprising:
forming a first conductive layer over a light receiving surface of a solar cell, the first conductive layer comprising silver, wherein the first conductive layer has a bulk resistivity in the range of 20-50 micro ohm cm, and wherein the first conductive layer has a pattern including a busbar and fingers connected to the busbar; and
forming a second conductive layer on the first conductive layer, the second conductive layer comprising silver, wherein the second conductive layer has a bulk resistivity in the range of 5-12 micro ohm cm, and wherein the bulk resistivity of the second conductive layer is at least three times lower than the bulk resistivity of the first conductive layer.

19. The method of claim 18, wherein the steps of forming the first conductive layer and the second conductive layer use ink deposition processes.

20. The method of claim 19, wherein the first conductive layer has a thickness in the range of 3-50 microns and a width in the range of 30-250 microns.

21. The method of claim 19, wherein the second conductive layer has a thickness in the range of 3-30 microns and a width in the range of 30-250 microns.

22. The method of claim 18, wherein the step of forming the first conductive layer comprises depositing a first ink solution over the light receiving surface and curing the first ink solution to form the first conductive layer.

23. The method of claim 22, wherein the step of forming the second conductive layer comprises depositing a second ink solution onto the first conductive layer and curing the second ink solution to form the second conductive layer.
